(19) United States
(12) Patent Application Publication
(10) Pub. No.: US 2011/0254017 A1
(43) Pub. Date: Oct. 20, 2011

(54) MANUFACTURING METHOD FOR CRYSTAL, CRYSTAL, AND SEMICONDUCTOR DEVICE

(75) Inventors: Taro Nishiguchi, Itami-shi (JP); Shin Harada, Osaka-shi (JP)

(73) Assignee: SUMITOMO ELECTRIC INDUSTRIES, LTD., Osaka-shi (JP)

(21) Appl. No.: 13/085,620

(22) Filed: Apr. 13, 2011

(30) Foreign Application Priority Data
Apr. 14, 2010 (JP) 2010-093046

(51) Int. Cl. H01L 29/24; C01B 31/36; C30B 23/02

(52) U.S. Cl. 257/77; 117/106; 423/345; 257/E29.104

(57) ABSTRACT

A manufacturing method for a crystal, a crystal, and a semiconductor device capable of growing a high-quality crystal are provided. The manufacturing method for a crystal of the present invention includes the steps of: preparing a seed crystal having a frontside surface and a backside surface opposite to the frontside surface; fixing the backside surface of the seed crystal to a pedestal; and growing the crystal on the frontside surface of the seed crystal. In the step of fixing, the seed crystal is fixed to the pedestal by coating the backside surface of the seed crystal with a Si layer or disposing a Si layer on the backside surface of the seed crystal, and carbonizing the Si layer.

### BACKGROUND OF THE INVENTION

1. Field of the Invention

The present invention relates to a manufacturing method for a crystal, a crystal, and a semiconductor device, and in particular to a manufacturing method for a crystal, a crystal, and a semiconductor device using a seed crystal.

2. Description of the Background Art

In recent years, silicon carbide (SiC) substrates have been adopted as semiconductor substrates for use in manufacturing semiconductor devices. SiC has a band gap larger than that of silicon (Si), which has been used more commonly in the field of semiconductor. Hence, a semiconductor device employing a SiC substrate advantageously has a large reverse breakdown voltage, low on-resistance, or has properties less likely to decrease in a high temperature environment.

The SiC substrate is manufactured using, for example, a sublimation method that allows a crystal to grow on a surface of a seed crystal. As a method of growing a crystal by the sublimation method, for example, the following two methods have been proposed.

Firstly, according to Japanese Patent Laying-Open No. 2001-139394 (Patent Document 1), when a single crystal is grown, a carbon composite structure having graphite fine particles and non-graphitizable carbon is formed in an interface between a seed crystal and a seed crystal pedestal. Patent Document 1 describes that, since carbon (C) is thereby uniformly formed all over an attachment surface using heat-resistant fine particles uniformly dispersed in the attachment surface as cores, and covers an attachment surface of the seed crystal, it is possible to prevent occurrence of recrystallization in the attachment surface of the seed crystal to be attached to the pedestal during growth of the single crystal, and it is also possible to prevent etching which may occur at a central portion of the seed crystal in an early stage of the growth.

Secondly, according to Japanese Patent Laying-Open No. 2003-226600 (Patent Document 2), a seed crystal having a backside surface coated with an organic thin film with a thickness of 0.5 to 5 μm is mechanically mounted on a graphite crucible lid. Patent Document 2 describes that, since the organic thin film can prevent sublimation of Si atoms from the backside surface of the seed crystal, generation of voids in a crystal is suppressed.

### SUMMARY OF THE INVENTION

In the technique of Patent Document 1 described above, there has been a possibility that strength of fixing between the seed crystal and the pedestal may be insufficient, depending on the material for the seed crystal. In particular, if the temperature between the seed crystal and the pedestal is set to a high temperature as in the case where, for example, a SiC crystal is grown, the strength of fixing described above has been likely to be reduced. Therefore, there has been a possibility that a portion or all of the seed crystal may be detached from the pedestal. Hence, there has been a possibility that the quality of the obtained crystal may be reduced.

As to the technique of Patent Document 2 described above, the present inventors have found as a result of examination that protection of the backside surface of the seed crystal is insufficient. For example, if a SiC seed crystal is used, the effect of preventing sublimation of the backside surface of the seed crystal is not sufficient, and as a result, there has been a possibility that the quality of the obtained crystal may be reduced.

The present invention has been made in view of the aforementioned problem, and one object of the present invention is to provide a manufacturing method for a crystal, a crystal, and a semiconductor device capable of growing a high-quality crystal.

A manufacturing method for a crystal of the present invention includes the steps of: preparing a seed crystal having a frontside surface and a backside surface opposite to the frontside surface; fixing the backside surface of the seed crystal to a pedestal; and growing the crystal on the frontside surface of the seed crystal. In the step of fixing, the seed crystal is fixed to the pedestal by coating the backside surface of the seed crystal with a silicon (Si) layer or disposing a silicon (Si) layer on the backside surface of the seed crystal, and carbonizing the Si layer.

According to the manufacturing method for a crystal of the present invention, the seed crystal and the pedestal are bonded using a layer obtained by carbonizing the Si layer. That is, the seed crystal and the pedestal are bonded by reaction. This can suppress a gap (void) from entering between the backside surface of the seed crystal and the layer obtained by carbonizing the Si layer, and between the layer obtained by carbonizing the Si layer and the pedestal. Therefore, occurrence of a gap between the seed crystal and the pedestal can be suppressed, and thus the seed crystal can be fixed to the pedestal uniformly and strongly, via the layer obtained by carbonizing the Si layer. Consequently, the quality of the crystal grown on the seed crystal can be improved.

Preferably, in the manufacturing method for the crystal described above, the Si layer is a polycrystal. Thereby, the Si layer can be formed easily.

Preferably, in the manufacturing method for the crystal described above, the Si layer is a single crystal. Thereby, a Si layer having a desired thermal expansion coefficient can be formed.

Preferably, in the manufacturing method for the crystal described above, the Si layer is amorphous. Thereby, reaction with C can be promoted.

Preferably, the manufacturing method for the crystal described above further includes the step of polishing the backside surface of the seed crystal, prior to the step of fixing.

Thereby, a damaged region in the backside surface of the seed crystal can be removed. This can further suppress occurrence of a gap between the backside surface of the seed crystal and the pedestal. Therefore, the seed crystal can be fixed to the pedestal more uniformly and more strongly, via the layer obtained by carbonizing the Si layer.

Preferably, the manufacturing method for the crystal described above further includes the step of polishing a region in the pedestal to which the seed crystal is to be fixed, prior to the step of fixing.

This can further reduce a gap between the Si layer and the pedestal. Therefore, the seed crystal can be fixed to the pedestal more uniformly and more strongly, via the layer obtained by carbonizing the Si layer.

Preferably, in the manufacturing method for the crystal described above, in the step of growing, a SiC crystal is grown. Thereby, a high-quality SiC crystal can be manufactured.

A crystal of the present invention is a crystal manufactured by the manufacturing method for the crystal described above, wherein the crystal is a single crystal. According to the crystal of the present invention, the crystal is manufactured with sublimation of the backside surface of the seed crystal being suppressed. Therefore, a single crystal with improved quality can be realized.

A semiconductor device of the present invention is fabricated using the crystal described above. According to the semiconductor device of the present invention, since a high-quality crystal is used, the quality of the semiconductor device can be improved.

As described above, with the manufacturing method for a crystal, the crystal, and the semiconductor device of the present invention, a high-quality crystal can be realized.

The foregoing and other objects, features, aspects and advantages of the present invention will become apparent from the following detailed description of the present invention when taken in conjunction with the accompanying drawings.

### BRIEF DESCRIPTION OF THE DRAWINGS

FIG. 1 is a cross sectional view schematically showing a crystal according to Embodiment 1 of the present invention.

FIG. 2 is a cross sectional view schematically showing each step of a manufacturing method for the crystal according to Embodiment 1 of the present invention.

FIG. 3 is a cross sectional view schematically showing each step of the manufacturing method for the crystal according to Embodiment 1 of the present invention.

FIG. 4 is a cross sectional view schematically showing each step of the manufacturing method for the crystal according to Embodiment 1 of the present invention.

FIG. 5 is a cross sectional view schematically showing each step of the manufacturing method for the crystal according to Embodiment 1 of the present invention.

FIG. 6 is a cross sectional view schematically showing each step of the manufacturing method for the crystal according to Embodiment 1 of the present invention.

FIG. 7 is a cross sectional view schematically showing each step of the manufacturing method for the crystal according to Embodiment 1 of the present invention.

FIG. 8 is a cross sectional view schematically showing each step of the manufacturing method for the crystal according to Embodiment 1 of the present invention.

FIG. 9 is a cross sectional view schematically showing each step of a manufacturing method for a crystal according to Embodiment 2 of the present invention.

FIG. 10 is a cross sectional view schematically showing each step of a manufacturing method for a crystal according to Embodiment 3 of the present invention.

FIG. 11 is a cross sectional view schematically showing each step of the manufacturing method for the crystal according to Embodiment 3 of the present invention.

FIG. 12 is a cross sectional view schematically showing a semiconductor device according to Embodiment 4 of the present invention.

FIG. 13 is a cross sectional view schematically showing each step of a manufacturing method for the semiconductor device according to Embodiment 4 of the present invention.

FIG. 14 is a cross sectional view schematically showing each step of the manufacturing method for the semiconductor device according to Embodiment 4 of the present invention.

FIG. 15 is a cross sectional view schematically showing each step of the manufacturing method for the semiconductor device according to Embodiment 4 of the present invention.

FIG. 16 is a cross sectional view schematically showing each step of the manufacturing method for the semiconductor device according to Embodiment 4 of the present invention.

FIG. 17 is a cross sectional view schematically showing a state where a seed crystal is mounted on a pedestal in comparative example 1.

FIG. 18 is a cross sectional view schematically showing a state where a seed crystal is mounted on a pedestal in comparative example 2.

### DESCRIPTION OF THE PREFERRED EMBODIMENTS

Hereinafter, embodiments of the present invention will be described with reference to the drawings. It is to be noted that, in the drawings below, identical or corresponding parts will be designated by the same reference numerals, and the description thereof will not be repeated. Further, in the present specification, an individual plane will be indicated by ( ) and a group plane will be indicated by { }. In addition, although a negative index is crystallographically supposed to be indicated by placing “-” (a bar) above a numeral, it will be indicated in the present specification by placing a minus sign before a numeral.

### Embodiment 1

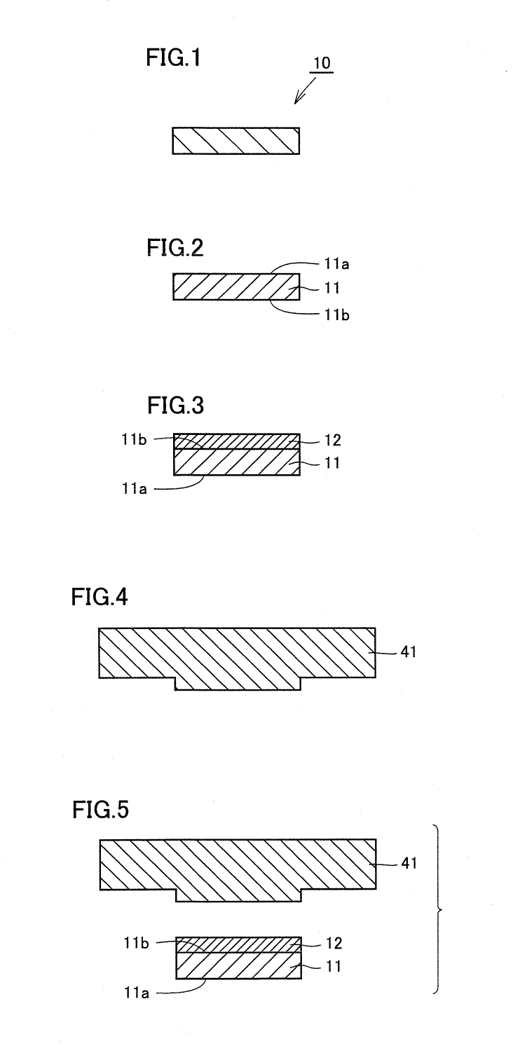

FIG. 1 is a cross sectional view schematically showing a crystal 10 according to Embodiment 1 of the present invention. Firstly, crystal 10 according to one embodiment of the present invention will be described with reference to FIG. 1.

Crystal 10 has high quality, which means that, for example, crystal 10 has a micropipe density of not more than 1 cm⁻². The micropipe density is a value measured for example by soaking crystal 10 in a potassium hydroxide (KOH) melt kept at 500° C. for 1 to 10 minutes, and performing a measurement on an etched surface thereof using a Nomarski differential interference microscope.

Preferably, crystal 10 is a SiC crystal. In this case, the polytype of the SiC crystal is preferably 4H—SiC, although it is not particularly limited. Further, preferably, crystal 10 is a single crystal.

FIGS. 2 to 7 are cross sectional views schematically showing each step of a manufacturing method for crystal 10 according to the embodiment of the present invention. Next, the manufacturing method for crystal 10 according to the present embodiment will be described with reference to FIGS. 1 to 7.

Firstly, as shown in FIG. 2, a seed crystal 11 is prepared. Seed crystal 11 has a frontside surface 11a as a surface on which the crystal will grow, and a backside surface 11b as a surface to be mounted on a pedestal. For example, seed crystal 11 is a SiC substrate. Seed crystal 11 has a thickness of, for example, not less than 0.5 mm and not more than 10 mm. In addition, the planar shape of seed crystal 11 is, for example, a circle, and the diameter thereof is preferably not less than 25 mm, and more preferably not less than 100 mm. Further, the tilt of the plane orientation of the seed crystal from the {0001} plane, that is, the off angle, is preferably not more than 8°.

Subsequently, backside surface 11b is polished to improve flatness of backside surface 11b. For the polishing, for example, diamond slurry can be used. The slurry contains diamond particles with a particle size of, for example, not less than 5 μm and not more than 100 μm, more preferably not less than 10 μm and not more than 20 μm.

Next, as shown in FIG. 3, backside surface 11b of seed crystal 11 is coated with a Si layer 12. In the present embodiment, Si layer 12 is formed to be in contact with backside surface 11b of seed crystal 11.

A method of forming Si layer 12 is not particularly limited, and, for example, a sputtering method can be employed. Si layer 12 may be any of a polycrystal, a single crystal, and amorphous. Further, the thickness of Si layer 12 is, for example, preferably not less than 1 μm and not more than 1 mm, and more preferably not less than 10 μm and not more than 0.1 mm.

Preferably, Si layer 12 is formed within backside surface 11b of seed crystal 11. That is, preferably, Si layer 12 is formed so as not to extend out of backside surface 11b.

Subsequently, as shown in FIG. 4, a pedestal 41 having a mounting surface on which seed crystal 11 is to be mounted is prepared. The mounting surface includes a surface preferably made of carbon. For example, pedestal 41 is made of graphite. Preferably, the mounting surface (region in pedestal 41 to be connected with Si layer 12) is polished to improve flatness of the mounting surface.

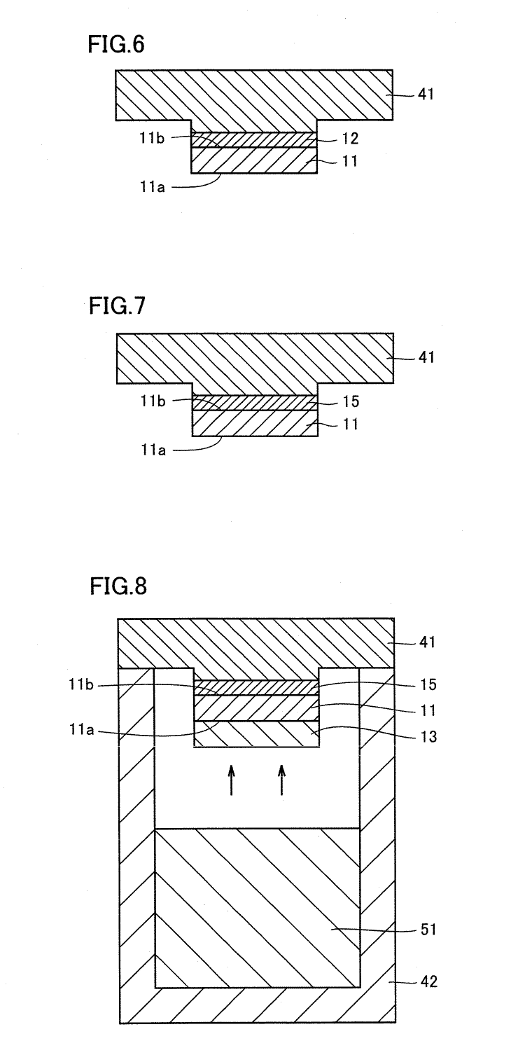

Next, as shown in FIGS. 5 and 6, backside surface 11b of seed crystal 11 is fixed to pedestal 41. In the step of fixing, seed crystal 11 is fixed to pedestal 41 by coating backside surface 11b of seed crystal 11 with the Si layer, and carbonizing Si layer 12. This step is performed, for example, as described below.

Firstly, as shown in FIG. 5, seed crystal 11 and pedestal 41 are disposed to face each other with Si layer 12 interposed therebetween. Then, as shown in FIG. 6, Si layer 12 is brought into contact with pedestal 41.

In this state, Si layer 12 is subjected to heat treatment. Thereby, as shown in FIG. 7, Si layer 12 is carbonized to form a fixing layer 15 containing C and Si. In the present embodiment, since seed crystal 11 and pedestal 41 contain C, the C element is diffused from at least one of seed crystal 11 and pedestal 41 into Si layer 12. Thereby, Si layer 12 is carbonized and becomes a layer containing SiC as fixing layer 15. Further, with fixing layer 15 formed by this carbonization, seed crystal 11 can be fixed to pedestal 41.

In the case where seed crystal 11 and pedestal 41 do not contain C, Si layer 12 can be carbonized by performing heat treatment in an atmosphere containing C.

Although conditions for the heat treatment are not particularly limited, the heat treatment is performed, for example, at a temperature of 1500° C., for a time period of three hours, under a pressure of not less than 1×10³ Pa, and in an inactive gas or nitrogen gas atmosphere. As an inactive gas, for example, helium (He), argon (Ar), or the like is used. The temperature for the heat treatment is preferably not less than 1300° C. and not more than 2000° C., and more preferably not less than 1414° C. and not more than 1550° C. In this case, carbonization of Si layer 12 can be further promoted.

When fixing layer 15 is formed as described above, an interface between fixing layer 15 and seed crystal 11 has a reduced gap, and has a void density of, for example, less than 10 cm⁻². The void density is a value measured for example by observing a cross section of the interface between seed crystal 11 and fixing layer 15 with a microscope.

Next, as shown in FIG. 8, a source material 51 is placed inside a crucible 42. If a crystal to be grown is a SiC crystal, for example, SiC powder is placed in crucible 42. Then, pedestal 41 is mounted on crucible 42 such that seed crystal 11 faces the inside of crucible 42. It is to be noted that pedestal 41 may function as a lid for crucible 42 as shown in FIG. 8.

Subsequently, a crystal 13 is grown on seed crystal 11. As a method of forming crystal 13, for example, the sublimation method (sublimation-recrystallization method) can be used. Specifically, crystal 13 can be grown by subliming source material 51 as indicated by arrows in the drawing, and depositing a sublimate on seed crystal 11. In the case where a SiC crystal is manufactured as crystal 13 using a SiC substrate as seed crystal 11, the temperature in the sublimation method is set, for example, to not less than 2100° C. and not more than 2500° C. Further, the pressure in the sublimation method is preferably set, for example, to not less than 1.3 kPa and not more than the atmospheric pressure, and more preferably set to not more than 13 kPa to increase a growth rate. Thereby, crystal 10 shown in FIG. 1 can be manufactured.

It is to be noted that crystal 13 grown on seed crystal 11 may be manufactured as crystal 10 shown in FIG. 1. Alternatively, crystal 10 may be manufactured by removing seed crystal 11 from manufactured crystal 13. Alternatively, crystal 10 shown in FIG. 1 may be manufactured as a substrate such as a SiC substrate, from crystal 13. Such a substrate is obtained, for example, by slicing crystal 13.

Further, although a crystal formed of SiC (SiC crystal) has been described as seed crystal 11 in the present embodiment, a crystal formed of another material may be used. As a material therefor, for example, gallium nitride (GaN), zinc selenide (ZnSe), zinc sulfide (ZnS), cadmium sulfide (CdS), cadmium telluride (CdTe), aluminum nitride (MN), boron nitride (BN), or the like can be used.

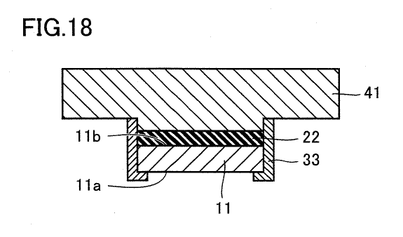

Subsequently, effects of crystal 10 and the manufacturing method therefor according to the present embodiment will be described in comparison to comparative example 1 shown in FIG. 17 and comparative example 2 shown in FIG. 18. FIGS. 17 and 18 are cross sectional views schematically showing states where seed crystal 11 is mounted on pedestal 41 in comparative examples 1 and 2.

As shown in FIG. 17, in comparative example 1, seed crystal 11 and pedestal 41 are bonded using an adhesive 31. In comparative example 1, strength of fixing between seed crystal 11 and pedestal 41 may be insufficient, depending on the material for seed crystal 11. In particular, if the temperature between seed crystal 11 and pedestal 41 is set to a high temperature as in the case where, for example, a SiC crystal is grown by the sublimation method, the strength of fixing described above is likely to be reduced. For example, an adhesion strength obtained by a fixing layer formed by hardening a carbon-based adhesive is likely to be reduced under a temperature of about 2000° C. generally used to grow a SiC crystal. As a result, a portion or all of seed crystal 11 may be detached from the pedestal, and thus the quality of obtained crystal 13 may be reduced. Further, in this case, while seed crystal 11 is often formed of SiC, and pedestal 41 is often formed of graphite, it is difficult to firmly fix the both using adhesive 31 due to material properties of the both. For example, although the fixing layer formed by hardening a carbon-based adhesive can bond carbon materials with high strength, the fixing layer cannot bond a carbon material and SiC with a comparable strength.

In addition, even when adhesive 31 can bond seed crystal 11 and pedestal 41 in comparative example 1, adhesive 31 should be heat treated to bond seed crystal 11 and pedestal 41. As a result of the heat treatment, adhesive 31 is thermally decomposed, and air bubbles are generated in adhesive 31. Thus, air bubbles are also present in an interface between seed crystal 11 and adhesive 31. Due to the air bubbles, there occurs a gap in an interface between adhesive 31 and pedestal 41.

In comparative example 2 shown in FIG. 18, seed crystal 11 provided with an organic thin film 22 with a thickness of 0.5 to 5 μm is fixed to pedestal 41 using a mechanical fixture 33. In comparative example 2, air bubbles may be generated in organic thin film 22 when backside surface 11b of seed crystal 11 is coated with organic thin film 22. That is, air bubbles are also generated between seed crystal 11 and organic thin film 22. Thus, there occurs a gap between seed crystal 11 and organic thin film 22.

Further, in comparative example 2, as shown in FIG. 18, seed crystal 11 and pedestal 41 are connected using fixture 33. Thus, there occurs a gap between seed crystal 11 and pedestal 41, specifically in an interface between organic thin film 22 and pedestal 41, due to a difference in thermal expansion coefficient between the material for seed crystal 11 and the material for pedestal 41.

Furthermore, even when adhesive 31 (see FIG. 17) is employed as means for connecting seed crystal 11 and pedestal 41, instead of fixture 33, in comparative example 2, there may occur a case where, when adhesive 31 is heat treated for bonding, not only organic thin film 22 but also adhesive 31 are thermally decomposed, and air bubbles are generated in organic thin film 22 and adhesive 31. Thus, air bubbles may also be present in an interface between seed crystal 11 and organic thin film 22, and an interface between pedestal 41 and adhesive 31.

If there occurs a gap between seed crystal 11 and adhesive 31 or between seed crystal 11 and organic thin film 22 as described above, backside surface 11b of seed crystal 11 is exposed to the atmosphere. In this case, since temperature distribution occurs within a growth surface of seed crystal 11 in accordance with distribution of the gap, a uniform crystal cannot be obtained. In addition, if a material transfers from seed crystal 11 into the gap due to sublimation or the like, composition distribution occurs within the growth surface of seed crystal 11, and as a result, there may occur a case where a uniform crystal cannot be obtained. In particular, if seed crystal 11 is formed of SiC, Si may transfer into the gap, and the transfer cannot be fully suppressed by organic thin film 22 with a thickness of about 0.5 to 5 Consequently, seed crystal 11 has a Si-deficient region, and a micropipe defect may occur in a portion of the crystal formed on seed crystal 11 which is located below this region.

In response to these problems, according to the present embodiment, seed crystal 11 is coated with Si layer 12, and seed crystal 11 is fixed to pedestal 41 using a layer obtained by carbonizing the Si layer (fixing layer 15). That is, seed crystal 11 and pedestal 41 are bonded by reaction. This can suppress a gap from entering between backside surface 11b of seed crystal 11 and fixing layer 15 obtained by carbonizing Si layer 12, and between fixing layer 15 obtained by carbonizing Si layer 12 and pedestal 41. Therefore, occurrence of a gap between seed crystal 11 and pedestal 41 can be suppressed, and thus seed crystal 11 can be fixed to pedestal 41 uniformly and strongly, via fixing layer 15 obtained by carbonizing Si layer 12. Consequently, the quality of crystal 13 grown on frontside surface 11a of seed crystal 11 can be improved.

In addition, as described above, since a gap as described above is less likely to occur due to fixing layer 15 obtained by reacting Si layer 12, seed crystal 11 is fixed to pedestal 41 uniformly and strongly. Thus, occurrence of composition distribution and temperature distribution in seed crystal 11 resulting from the gap is suppressed, and thereby heat conduction in entire seed crystal 11 during crystal growth is uniformized. Hence, crystals 10 and 13 having uniform quality can be manufactured. It is to be noted that the temperature distribution can further be suppressed by polishing one or both of the backside surface of seed crystal 11 and the mounting surface of pedestal 41.

Further, in the present embodiment, it is preferable to manufacture a SiC crystal as crystals 10 and 13, using a SiC crystal as seed crystal 11 and using graphite as pedestal 41. In this case, the C element constituting seed crystal 11 and pedestal 41 is diffused into Si layer 12 and thus Si layer 12 is easily carbonized, fixing layer 15 containing SiC can be easily formed. Further, since fixing layer 15 is a SiC layer formed by carbonizing Si layer 12, a difference in thermal expansion coefficient between fixing layer 15 and each of seed crystal 11 and pedestal 41 is small. This can suppress a gap from occurring between seed crystal 11 and pedestal 41 due to the difference in thermal expansion coefficient. Therefore, backside surface 11b of seed crystal 11 can be bonded to pedestal 41 more uniformly and strongly, and thus the quality of the SiC crystal grown on frontside surface 11a of seed crystal 11 can be further improved.

### Embodiment 2

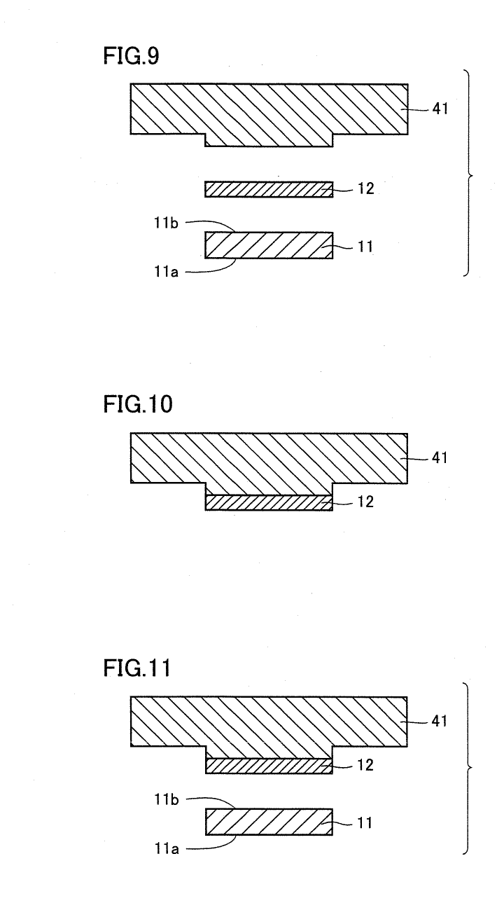

A crystal according to the present embodiment is the same as crystal 10 according to Embodiment 1 shown in FIG. 1. However, the present embodiment is different from Embodiment 1 in the manufacturing method for crystal 10. A manufacturing method for a crystal according to the present embodiment will be described with reference to FIGS. 2, 4, and 6 to 9. It is to be noted that FIG. 9 is a cross sectional view schematically showing each step of the manufacturing method for the crystal according to the present embodiment.

Firstly, seed crystal 11 shown in FIG. 2 and pedestal 41 shown in FIG. 4 are prepared. In addition, Si layer 12 shown in FIG. 9 is prepared. Si layer 12 is, for example, in the form of a plate (Si plate). Preferably, Si layer 12 has a peripheral edge equal to the planar shape of backside surface 11b of seed crystal 11, and a region in pedestal 41 on which seed crystal 11 is to be mounted (in the present embodiment, the planar shape of a protruding portion), or smaller than peripheral edges thereof. That is, preferably, Si layer 12 has a shape so as not to extend out of a region sandwiched between seed crystal 11 and pedestal 41.

Next, as shown in FIG. 9, Si layer 12 is disposed between pedestal 41 and backside surface 11b of seed crystal 11. Then, as shown in FIG. 6, Si layer 12 is brought into contact with each of pedestal 41 and backside surface 11b of seed crystal 11. Subsequently, as in Embodiment 1, Si layer 12 is carbonized to form fixing layer 15, and thereby seed crystal 11 is fixed to pedestal 41 as shown in FIG. 7.

Then, as in Embodiment 1 shown in FIG. 8, crystal 13 is grown on frontside surface 11a of seed crystal 11. Thereby, the crystal according to the present embodiment can be manufactured.

### Embodiment 3

A crystal according to the present embodiment is the same as crystal 10 according to Embodiment 1 shown in FIG. 1. However, the present embodiment is different from Embodiment 1 in the manufacturing method for crystal 10. A manufacturing method for a crystal according to the present embodiment will be described with reference to FIGS. 2, 4, 6 to 8, 10, and 11. It is to be noted that FIGS. 10 and 11 are cross sectional views schematically showing each step of the manufacturing method for the crystal according to the present embodiment.

Firstly, seed crystal 11 shown in FIG. 2 and pedestal 41 shown in FIG. 4 are prepared. Then, as shown in FIG. 10, Si layer 12 is formed on pedestal 41. A method of forming Si layer 12 is not particularly limited, and, for example, the sputtering method can be used.

Thereafter, as shown in FIG. 11, backside surface 11b of seed crystal 11 and Si layer 12 are caused to face each other, and Si layer 12 is disposed on the side of backside surface 11b of seed crystal 11. Then, as shown in FIG. 6, Si layer 12 is brought into contact with backside surface 11b of seed crystal 11. Subsequently, as in Embodiment 1, Si layer 12 is carbonized to form fixing layer 15, and thereby seed crystal 11 is fixed to pedestal 41 as shown in FIG. 7.

Then, as in Embodiment 1 shown in FIG. 8, crystal 13 is grown on frontside surface 11a of seed crystal 11. Thereby, the crystal according to the present embodiment can be manufactured.

### Embodiment 4

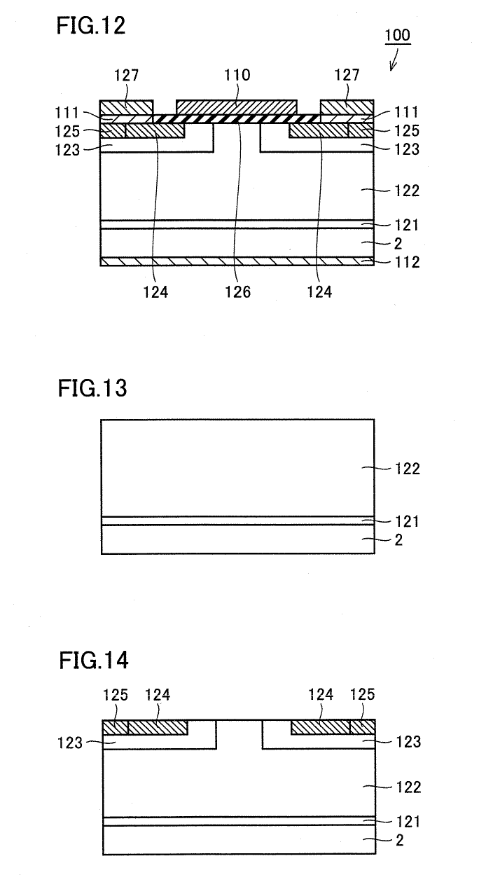

FIG. 12 is a cross sectional view schematically showing a semiconductor device 100 according to Embodiment 4 of the present invention. Semiconductor device 100 according to the present embodiment will be described with reference to FIG. 12.

As shown in FIG. 12, semiconductor device 100 according to the present embodiment is a vertical DiMOSFET (Double Implanted Metal Oxide Semiconductor Field Effect Transistor), including a substrate 2, a buffer layer 121, a reverse breakdown voltage holding layer 122, a p region 123, an n⁺ region 124, a p⁺ region 125, an oxide film 126, a source electrode 111, an upper source electrode 127, a gate electrode 110, and a drain electrode 112.

Substrate 2 is fabricated from crystal 10 (see FIG. 1) or crystal 13 (see FIG. 8) manufactured by the manufacturing method for the crystal described in Embodiments 1 to 3. In the present embodiment, substrate 2 has an n-type conductivity type.

Drain electrode 112 is provided below substrate 2. Buffer layer 121 is provided on substrate 2. Buffer layer 121 has an n-type conductivity type, and has a thickness of, for example, 0.5 μm. Further, n-type conductive impurities in buffer layer 121 have a concentration of, for example, 5×10¹⁷ cm⁻³.

Reverse breakdown voltage holding layer 122 is formed on buffer layer 121, and is made of SiC having an n-type conductivity type. For example, reverse breakdown voltage holding layer 122 has a thickness of 10 μm, and n-type conductive impurities therein have a concentration of 5×10¹⁵ cm⁻³.

In a surface of reverse breakdown voltage holding layer 122, a plurality of p regions 123 having a p-type conductivity type are formed to be spaced from each other. Within p region 123, n⁺ region 124 is formed at a surface layer of p region 123. Further, p⁺ region 125 is formed at a position adjacent to n⁺ region 124. Oxide film 126 is formed to extend from above n⁺ region 124 in one p region 123, the one p region 123, reverse breakdown voltage holding layer 122 exposed between two p regions 123, the other p region 123, to above n⁺ region 124 in the other p region 123. Gate electrode 110 is formed on oxide film 126. Further, source electrode 111 is formed on n⁺ region 124 and p⁺ region 125. Upper source electrode 127 is formed on source electrode 111.

Nitrogen atoms in a region that is within 10 nm from an interface between oxide film 126 and n⁺ region 124, p⁺ region 125, p region 123, and reverse breakdown voltage holding layer 122 serving as a semiconductor layer have a maximum concentration value of not less than 1×10²¹ cm⁻³. Thereby, in particular, mobility in a channel region below oxide film 126 (i.e., a portion in contact with oxide film 126, including p region 123 between n⁺ region 124 and reverse breakdown voltage holding layer 122) can be improved.

Subsequently, a manufacturing method for semiconductor device 100 according to the present embodiment will be described with reference to FIGS. 12 to 16. FIGS. 13 to 16 are cross sectional views schematically showing each step of the manufacturing method for semiconductor device 100 according to the present embodiment.

Firstly, as shown in FIG. 13, substrate 2 is prepared. For substrate 2, crystal 10 or 13 manufactured by the manufacturing method for the crystal according to Embodiments 1 to 3 is used. Crystal 10 or 13 may be used as substrate 2, and substrate 2 may be cut out from crystal 10 or 13 and fabricated. Preferably, substrate 2 is a SiC substrate. As substrate 2, for example, a substrate having an n-type conductivity type and a substrate resistance of 0.02 Ωcm may be used.

Next, as shown in FIG. 13, buffer layer 121 and reverse breakdown voltage holding layer 122 are formed as described below. Firstly, buffer layer 121 is formed on a frontside surface of substrate 2. Buffer layer 121 is an epitaxial layer made of, for example, SiC having an n-type conductivity type, with a thickness of, for example, 0.5 μm. Further, conductive impurities in buffer layer 121 have a concentration of, for example, 5×10¹⁷ cm⁻³.

Subsequently, reverse breakdown voltage holding layer 122 is formed on buffer layer 121. Specifically, a layer made of SiC having an n-type conductivity type is formed by an epitaxial growth method. Reverse breakdown voltage holding layer 122 has a thickness of, for example, 10 μm. Further, n-type conductive impurities in reverse breakdown voltage holding layer 122 have a concentration of, for example, 5×10¹⁵ cm⁻³.

Next, as shown in FIG. 14, p region 123, n⁺ region 124, and p⁺ region 125 are formed as described below. Firstly, p region 123 is formed by selectively implanting impurities having a p-type conductivity type in a portion of reverse breakdown voltage holding layer 122. Thereafter, n⁺ region 124 is formed by selectively implanting n-type conductive impurities in a predetermined region, and p⁺ region 125 is formed by selectively implanting p-type conductive impurities in a predetermined region. Selective implantation of impurities is performed using, for example, a mask made of an oxide film.

After the implantation step as described above, activation annealing treatment is performed. Annealing is performed, for example, in an argon atmosphere at a heating temperature of 1700° C. for 30 minutes.

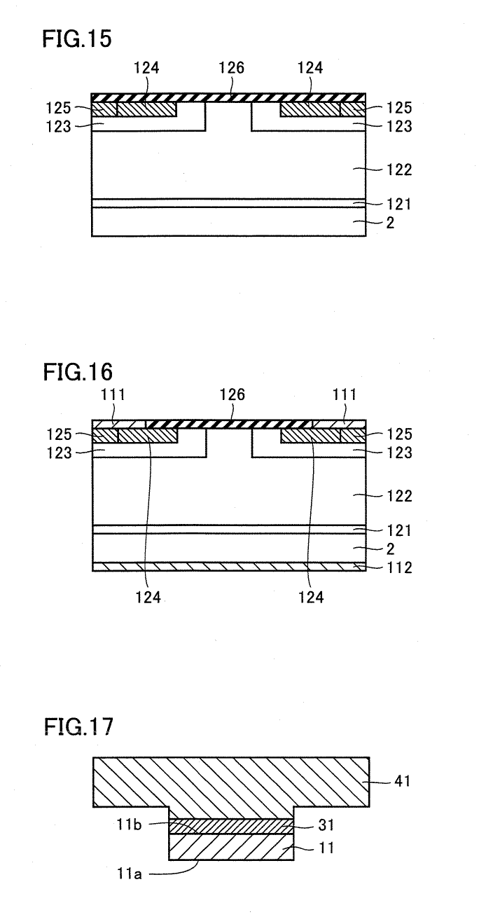

Subsequently, referring to FIG. 15, oxide film 126 as a gate insulating film is formed. Specifically, oxide film 126 is formed to cover reverse breakdown voltage holding layer 122, p region 123, n⁺ region 124, and p⁺ region 125. The formation may be performed by dry oxidation (thermal oxidation). Dry oxidation is performed under conditions of, for example, a heating temperature of 1200° C. and a heating time period of 30 minutes.

Thereafter, a nitrogen annealing step is performed. Specifically, annealing treatment is performed in a nitric oxide (NO) atmosphere. The treatment is performed under conditions of, for example, a heating temperature of 1100° C. and a heating time period of 120 minutes. As a result, nitrogen atoms can be introduced into the proximity of the interface between oxide film 126 and each of reverse breakdown voltage holding layer 122, p region 123, n⁺ region 124, and p⁺ region 125.

After the annealing step using nitric oxide, annealing treatment using argon gas as an inert gas may be further performed. The treatment is performed under conditions of, for example, a heating temperature of 1100° C. and a heating time period of 60 minutes.

Next, as shown in FIG. 16, source electrode 111 is formed as described below. Firstly, a resist film having a pattern is formed on oxide film 126, using a photolithography method. The resist film is used as a mask to remove a portion of oxide film 126 located above n⁺ region 124 and p⁺ region 125 by etching. Thereby, an opening is formed in oxide film 126. Then, a conductor film is formed to come into contact with each of n⁺ region 124 and p⁺ region 125 in the opening. Subsequently, the resist film is removed to perform removal (lift-off) of a portion of the conductor film located on the resist film. The conductor film may be a metal film, and made of, for example, nickel (Ni). As a result of the lift-off, source electrode 111 is formed.

Here, it is preferable to perform heat treatment for alloying. For example, heat treatment is performed in an atmosphere of argon (Ar) gas as an inert gas, at a heating temperature of 950° C., for two minutes.

Next, as shown in FIG. 12, upper source electrode 127 is formed on source electrode 111. Further, drain electrode 112 is formed on a backside surface of substrate 2. By performing the above steps, semiconductor device 100 shown in FIG. 12 can be manufactured. It is to be noted that a configuration employing conductivity types opposite to those in the present embodiment, that is, a configuration in which p-type and n-type are opposite, can also be used.

In addition, substrate 2 for fabricating semiconductor device 100 is not limited to SiC, and may be fabricated using a crystal made of another material.

Further, although a vertical DiMOSFET has been illustrated in the present embodiment, other semiconductor devices may be manufactured using a semiconductor substrate according to the present invention, and for example, a RESURF-JFET (Reduced Surface Field-Junction Field Effect Transistor), a schottky diode (SBD), and the like may be manufactured.

### EXAMPLES

In the present examples, an effect of fixing the seed crystal to the pedestal by coating the backside surface of the seed crystal with a Si layer or disposing a Si layer on the backside surface of the seed crystal, and carbonizing the Si layer was examined.

### The Present Invention's Example 1

A manufacturing method for a crystal according to the present invention's example 1 was basically in accordance with Embodiment 1 described above. Firstly, as shown in FIG. 2, a SiC substrate having a thickness of about 3 mm, a diameter of 60 mm, a polytype of 4H, and a plane orientation of (000-1) was prepared as seed crystal 11.

Next, a backside surface of seed crystal 11 was mechanically polished using diamond slurry having a particle size of about 15 μm.

Then, as shown in FIG. 3, a Si layer with a thickness of 10 μm was formed on backside surface 11b of seed crystal 11 by the sputtering method.

Subsequently, as shown in FIG. 4, graphite pedestal 41 having a mounting surface on which seed crystal 11 was to be mounted was prepared. Thereafter, the mounting surface was polished using diamond slurry.

Next, as shown in FIG. 5, backside surface 11b of seed crystal 11 and pedestal 41 were caused to face each other, and, as shown in FIG. 6, Si layer 12 was brought into contact with pedestal 41. In this state, heat treatment was performed. The heat treatment was performed, for example, under a pressure of 1×10³ Pa, in an argon atmosphere, at 1500° C. for three hours. Thus, Si layer 12 was carbonized to form fixing layer 15 containing SiC as shown in FIG. 7, and thereby seed crystal 11 was fixed to pedestal 41.

Then, as shown in FIG. 8, SiC powder as source material 51 was placed inside graphite crucible 42. Next, pedestal 41 was mounted such that seed crystal 11 faced the inside of crucible 42 and pedestal 41 functioned as a lid for crucible 42.

Subsequently, a SiC crystal as crystal 13 was grown on seed crystal 11 by the sublimation method. The SiC crystal was grown at a temperature of 2400° C. and a pressure of 1.7 kPa, for 300 hours. Thereby, the SiC crystal as crystal 13 was manufactured on seed crystal 11.

Next, the obtained SiC crystal was sliced to obtain a SiC substrate. As a result of evaluating a surface of the SiC substrate, it had a void density of 0/cm² and a micropipe density of 1/cm².

The void density was measured by observing a cross section of the interface between seed crystal 11 and fixing layer 15 with a microscope. The micropipe density was measured by soaking the SiC substrate in a KOH melt kept at 500° C. for 1 to 10 minutes, and performing a measurement on an etched surface thereof using a Nomarski differential interference microscope.

### The Present Invention's Example 2

A manufacturing method for a crystal according to the present invention's example 2 was basically in accordance with Embodiment 2 described above. Although the manufacturing method for a crystal according to the present invention's example 2 had a configuration similar to that of the present invention's example 1, the present invention's example 2 was different from the present invention's example 1 in the step of fixing backside surface 11b of seed crystal 11 to pedestal 41.

Specifically, firstly, seed crystal 11 and pedestal 41 identical to those in the present invention's example 1 were prepared. Further, a Si substrate with a thickness of 0.1 mm and a diameter of 60 mm was prepared as Si layer 12. Thereafter, as shown in FIG. 9, seed crystal 11 and pedestal 41 were disposed to sandwich the Si substrate therebetween. That is, Si layer 12 was disposed on backside surface 11b of seed crystal 11. Subsequently, as in the present invention's example 1, heat treatment was performed to carbonize the Si substrate, and thereby seed crystal 11 was fixed to pedestal 41.

When a surface of the SiC substrate obtained in the present invention's example 2 was evaluated as in the present invention's example 1, it had a void density of 0/cm² and a micropipe density of 1/cm².

### Comparative Example 1

In comparative example 1, a SiC crystal was manufactured basically as in the present invention's example 1. However, comparative example 1 was different from the present invention's example 1 in that seed crystal 11 and pedestal 41 were bonded using adhesive 31, as shown in FIG. 17.

Specifically, as adhesive 31, an adhesive including a phenol resin, phenol, ethyl alcohol, formaldehyde, water, and a solid carbon component was prepared. Seed crystal 11 and pedestal 41 were brought into contact with each other, with adhesive 31 interposed therebetween. Adhesive 31 was applied in an amount of about 25 mg/cm², with a thickness of about 40 μm. The contact was performed under conditions of a temperature of 100° C. and a pressure of 0.1 MPa. Thereafter, adhesive 31 was prebaked. As conditions therefor, heat treatment at 80° C. for four hours, heat treatment at 120° C. for four hours, and heat treatment at 200° C. for one hour were successively performed. Next, adhesive 31 was calcined. Heating therefor was performed at 1150° C. for one hour in a helium gas atmosphere at 80 kPa.

In comparative example 1, seed crystal 11 fell from pedestal 41 with a probability of one third while the temperature was increasing to perform the sublimation method or while the crystal was growing. When a surface of a SiC substrate obtained in the case where the falling did not occur was evaluated as in the present invention's example 1, it had a void density of 10/cm² and a micropipe density of 50/cm². That is, in the case of comparative example 1, even in the SiC substrate obtained in the case where seed crystal 11 did not fall, a gap occurred and thus crystallinity was deteriorated.

### Comparative Example 2

In comparative example 2, a SiC crystal was manufactured basically as in the present invention's example 1. However, comparative example 2 was different from the present invention's example 1 in that seed crystal 11 provided with 10 μm-thick organic thin film 22 instead of Si layer 12 was fixed to pedestal 41 using mechanical fixture 33, as shown in FIG. 18.

When a surface of a SiC substrate obtained in comparative example 2 was evaluated as in the present invention's example 1, it had a void density of 120/cm² and a micropipe density of 300/cm². That is, in the case of comparative example 2, although it was possible to suppress seed crystal 11 from falling, a gap occurred and thus crystallinity was deteriorated.

As described above, according to the present examples, it was possible to confirm that occurrence of a gap in the interface between seed crystal 11 and Si layer 12 can be reduced and the quality of the grown crystal can be improved, by fixing the seed crystal to the pedestal by coating the backside surface of the seed crystal with a Si layer or disposing a Si layer on the backside surface of the seed crystal, and carbonizing the Si layer.

Although the embodiments and examples of the present invention have been described above, it is also originally intended to combine features of the embodiments and examples as appropriate. Although the present invention has been described and illustrated in detail, it is clearly understood that the same is by way of illustration and example only and is not to be taken by way of limitation, the scope of the present invention being interpreted by the terms of the appended claims.

What is claimed is:

1. A manufacturing method for a crystal, comprising the steps of:
preparing a seed crystal having a frontside surface and a backside surface opposite to said frontside surface;
fixing said backside surface of said seed crystal to a pedestal; and
growing the crystal on said frontside surface of said seed crystal,
wherein, in said step of fixing, said seed crystal is fixed to said pedestal by coating said backside surface of said seed crystal with a silicon layer or disposing a silicon layer on said backside surface of said seed crystal, and carbonizing said silicon layer.

2. The manufacturing method for the crystal according to claim 1, wherein said silicon layer is a polycrystal.

3. The manufacturing method for the crystal according to claim 1, wherein said silicon layer is a single crystal.

4. The manufacturing method for the crystal according to claim 1, wherein said silicon layer is amorphous.

5. The manufacturing method for the crystal according to claim 1, further comprising the step of polishing said backside surface of said seed crystal, prior to said step of fixing.

6. The manufacturing method for the crystal according to claim 1, further comprising the step of polishing a region in said pedestal to which said seed crystal is to be fixed, prior to said step of fixing.

7. The manufacturing method for the crystal according to claim 1, wherein, in said step of growing, a silicon carbide crystal is grown.

8. A crystal manufactured by the manufacturing method for the crystal according to claim 1, wherein the crystal is a single crystal.

9. A semiconductor device fabricated using the crystal according to claim 8.
